(19) United States
(12) Patent Application Publication
(10) Pub. No.: US 2024/0244819 A1
(43) Pub. Date: Jul. 18, 2024

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Erh-Kun LAI, Taichung City (TW); Feng-Min LEE, Hsinchu City (TW)

(21) Appl. No.: 18/188,612

(22) Filed: Mar. 23, 2023

Related U.S. Application Data
(60) Provisional application No. 63/438,796, filed on Jan. 13, 2023.

(51) Int. Cl. H10B 12/00

(52) U.S. Cl. CPC H10B 12/20

(57) ABSTRACT

A semiconductor structure is provided. The semiconductor structure has a device defining region. The device defining region includes a first portion and a second portion separated from each other. The semiconductor structure includes a stack. The stack includes first conductive layers and first dielectric layers disposed alternately. The stack has an opening through the stack in the device defining region. The semiconductor structure further includes a second conductive layer, a first conductive pillar, a third conductive layer, a second conductive pillar, and a third conductive pillar. The second conductive layer is disposed along a sidewall of the opening. The first conductive pillar is disposed in the opening in the first portion. The third conductive layer is disposed in the opening along an edge of the second portion. The second conductive pillar and the third conductive pillar are disposed in the second portion and separated from each other.

This application claims the benefit of U.S. provisional application Ser. No. 63/438,796, filed Jan. 13, 2023, the subject matter of which is incorporated herein by reference.

### TECHNICAL FIELD

This disclosure relates to a semiconductor structure and a method for manufacturing the same. More particularly, this disclosure relates to a semiconductor structure comprising a 3D DRAM structure and a method for manufacturing the same.

### BACKGROUND

As the development of semiconductor industry, three dimensional (3D) structures for various electronic devices have been proposed for the purposes of increase the density, decrease the volume, and so on. For some types of electronic devices, such as dynamic random access memory (DRAM), the means to achieve a 3D structure is to stack two dimensional (2D) structures layer by layer. Such a 3D structure allows for more electronic devices in a small footprint, but is not beneficial for cost reduction.

### SUMMARY

This disclosure is focused on improvement of 3D structures, such that an electronic device, such as DRAM, can be manufactured in a cost saving manner.

In one aspect of the disclosure, a semiconductor structure is provided. The semiconductor structure has a device defining region. The device defining region includes a first portion and a second portion separated from each other. The semiconductor structure comprises a stack. The stack comprises a plurality of first conductive layers and a plurality of first dielectric layers disposed alternately. The stack has an opening through the stack in the device defining region. The semiconductor structure further comprises a second conductive layer, a first conductive pillar, a third conductive layer, a second conductive pillar, and a third conductive pillar. The second conductive layer is disposed along a sidewall of the opening. The first conductive pillar is disposed in the opening in the first portion of the device defining region. The third conductive layer is disposed in the opening along an edge of the second portion of the device defining region. The second conductive pillar and the third conductive pillar are disposed in the second portion and separated from each other.

In another aspect of the disclosure, a method for manufacturing a semiconductor structure is provided. The semiconductor structure has a device defining region. The device defining region including a first portion and a second portion separated from each other. The method comprises following steps. First, a stack is formed, the stack comprises a plurality of first conductive layers and a plurality of first dielectric layers disposed alternately, and the stack has an opening through the stack in the device defining region. Then, a second conductive layer is formed along a sidewall of the opening. A first conductive pillar is formed in the opening in the first portion of the device defining region. A third conductive layer is formed in the opening along an edge of the second portion of the device defining region. A second conductive pillar and a third conductive pillar are formed in the second portion, and the second conductive pillar and the third conductive pillar are separated from each other.

### BRIEF DESCRIPTION OF THE DRAWINGS

FIGS. 1A-1C illustrate an exemplary semiconductor structure and a DRAM structure thereof.

FIG. 2 illustrates another exemplary semiconductor structure and a DRAM structure thereof.

FIG. 3 illustrates still another exemplary semiconductor structure and a DRAM structure thereof.

FIG. 4 illustrates a further exemplary semiconductor structure and DRAM structures thereof.

FIGS. 5A-5M illustrate various stages of an exemplary method for manufacturing a semiconductor structure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

One aspect of the disclosure is directed to a semiconductor structure. The semiconductor structure has a device defining region. The defining region includes a first portion and a second portion separated from each other. The semiconductor structure comprises a stack. The stack comprises a plurality of first conductive layers and a plurality of first dielectric layers disposed alternately. The stack has an opening through the stack in the device defining region. The semiconductor structure further comprises a second conductive layer, a first conductive pillar, a third conductive layer, a second conductive pillar, and a third conductive pillar. The second conductive layer is disposed along a sidewall of the opening. The first conductive pillar is disposed in the opening in the first portion of the device defining region. The third conductive layer is disposed in the opening along an edge of the second portion of the device defining region. The second conductive pillar and the third conductive pillar are disposed in the second portion and separated from each other.

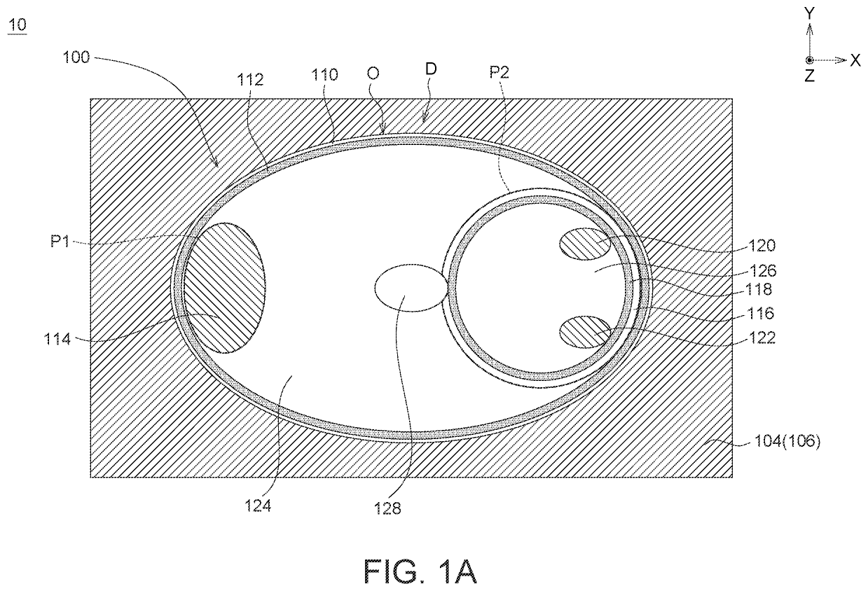

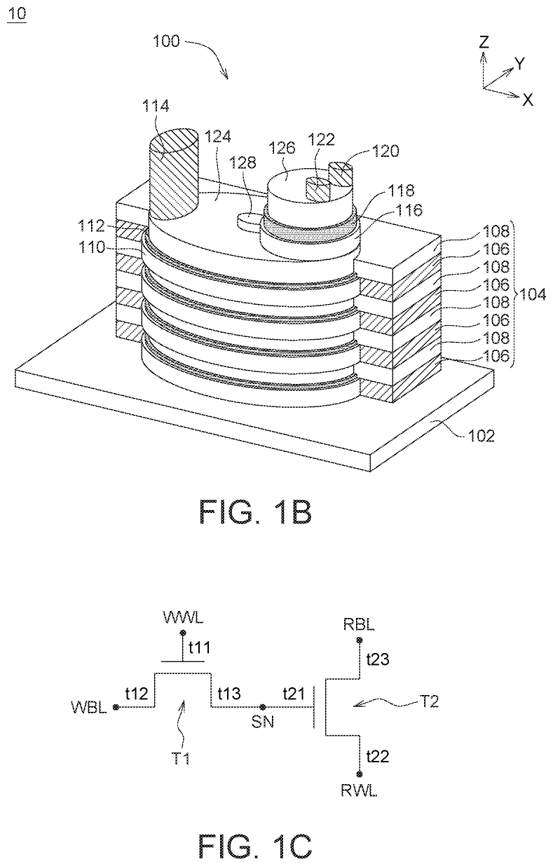

FIGS. 1A-1C shows an exemplary semiconductor structure 10 and a DRAM structure 100 thereof. FIG. 1A is a top view of the semiconductor structure 10, in which the topmost first dielectric layer 108 is removed for clarity. FIG. 1B is a perspective view of the semiconductor structure 10, in which some portion of some elements are enlarged, and some portion of some other elements are omitted for clarity. FIG. 1C is an exemplary circuit diagram for a DRAM cell of the DRAM structure 100.

The semiconductor structure 10 has a device defining region D. Herein, the device defining region D can be realized as a region of the semiconductor structure 10 in which an electronic device, such as DRAM, having a 3D structure is formed, and thus can be defined to encompass areas of the elements and portions of elements forming the DRAM structure 100. The device defining region D includes a first portion P1 and a second portion P2 separated from each other.

The semiconductor structure 10 can comprise a substrate 102. Any suitable substrate can be used, and any suitable layer, including but not limited to a circuit layer, an interlayer dielectric layer, etc., can be disposed thereon, without particular limit.

The semiconductor structure 10 comprises a stack 104, which can be disposed on the substrate 102. The stack 104 comprises a plurality of first conductive layers 106 and a plurality of first dielectric layers 108 disposed alternately. A stacking direction of the stack 104 is substantially perpendicular to the substrate 102 (i.e., the Z direction in the drawings). In other words, the first conductive layers 106 and the first dielectric layers 108 are stacked in the stacking direction substantially perpendicular to the substrate 102. The stack 104 has an opening O through the stack 104 in the device defining region D.

The semiconductor structure 10 can further comprise a second dielectric layer 110 disposed on a sidewall of the opening O. The semiconductor structure 10 comprises a second conductive layer 112. The second conductive layer 112 is disposed on the second dielectric layer 110. As such, the second conductive layer 112 can be disposed along the sidewall of the opening O. In the semiconductor structure 10, as shown in FIG. 1B, the second conductive layer 112 discontinuously extends in the stacking direction of the stack104. More specifically, the second conductive layer 112 can comprise a plurality of discontinuous portions corresponding to the first conductive layers 106, respectively.

The semiconductor structure 10 comprises a first conductive pillar 114. The first conductive pillar 114 is disposed in the opening O in the first portion P1 of the device defining region D. In some embodiments, the scope of the first portion P1 is decided substantially according to the first conductive pillar 114, and the first conductive pillar 114 forms an edge of the first portion P1. The first conductive pillar 114 can continuously extend across the whole stack 104 in the stacking direction.

The semiconductor structure 10 can further comprise a third dielectric layer 116 disposed as an outermost layer of the second portion P2. In such a condition, the scope of the second portion P2 is decided substantially according to the third dielectric layer 116, and the third dielectric layer 116 forms an edge of the second portion P2. The semiconductor structure 10 comprises a third conductive layer 118. The third conductive layer 118 is disposed on the third dielectric layer 116. As such, the third conductive layer 118 can be disposed in the opening O along the edge of the second portion P2 of the device defining region D. The third dielectric layer 116 and the third conductive layer 118 can continuously extend across the whole stack 104 in the stacking direction.

The semiconductor structure 10 comprises a second conductive pillar 120 and a third conductive pillar 122. The second conductive pillar 120 and the third conductive pillar 122 are disposed in the second portion P2 and separated from each other. Similar to the first conductive pillar 114, the second conductive pillar 120 and the third conductive pillar 122 can continuously extend across the whole stack 104 in the stacking direction.

The semiconductor structure 10 can further comprise a first dielectric material 124 filling a remaining space of the opening O except for the first portion P1 and the second portion P2. The semiconductor structure 10 can further comprise a second dielectric material 126 filling a remaining space of the second portion P2.

According to some embodiments, the semiconductor structure 10 can further comprise a place holder 128 disposed in a central portion of the device defining region D. The first portion P1 and the second portion P2 are positioned at two opposite sides of the place holder 128.

The DRAM structure 100 is disposed on the substrate 102, and can be constituted by the elements described above. For example, the first conductive layers 106, the second conductive layer 112, and the first conductive pillar 114 form first transistors T1 of the DRAM structure 100, and the second conductive layer 112, the third conductive layer 118, the second conductive pillar 120, and the third conductive pillar 122 form second transistors T2 of the DRAM structure 100. Specifically, the DRAM structure 100 comprises a plurality of DRAM cells. The DRAM cells can be 2T0C cells. In other words, each DRAM cell can be composed of a first transistor T1 and a second transistor T2, without a capacitor. A corresponding first conductive layer 106, a portion of the second conductive layer 112 corresponding to the corresponding first conductive layer 106, and the first conductive pillar 114 form the first transistor T1. The portion of the second conductive layer 112 corresponding to the corresponding first conductive layer 106, the third conductive layer 118, the second conductive pillar 120, and the third conductive pillar 122 form the second transistor T2. More specifically, the corresponding first conductive layer 106 can form a first terminal t11 of the first transistor T1, the first conductive pillar 114 can form a second terminal t12 of the first transistor T1, and the portion of the second conductive layer 112 corresponding to the corresponding first conductive layer 106 can form a channel and a third terminal t13 of the first transistor T1. The portion of the second conductive layer 112 corresponding to the corresponding first conductive layer 106 can form a first terminal t21 of the second transistor T2, the second conductive pillar 120 can form a second terminal t22 of the second transistor T2, the third conductive pillar 122 can form a third terminal t23 of the second transistor T2, and the third conductive layer 118 can form a channel of the second transistor T2.

As shown in FIG. 1C, the first transistor T1 can be a write transistor, and the second transistor T2 can be a read transistor. The first terminal t11 of the first transistor T1 can be a gate terminal of the first transistor T1, and in some embodiments, can be further connected to a write word line WWL. The second terminal t12 of the first transistor T1 can be a drain terminal of the first transistor T1, and in some embodiments, can be further connected to a write bit line WBL. The third terminal t13 of the first transistor T1 can be a source terminal of the first transistor T1, and can be connected to the first terminal t21 of the second transistor T2. The first terminal t21 of the second transistor T2 can be a gate terminal of the second transistor T2. A storage node SN can be formed between the third terminal t13 of the first transistor T1 and the first terminal t21 of the second transistor T2. The second terminal t22 of the second transistor T2 can be a drain terminal of the second transistor T2, and in some embodiments, can be further connected to a read word line RWL. The third terminal t23 of the second transistor T2 can be a source terminal of the second transistor T2, and in some embodiments, can be further connected to a read bit line RBL.

Specific examples for operations of a n^{st} DRAM cell are provided herein and listed in Table 1 for further understanding, but the disclosure is not limited thereto, For programming a logic state “1”, a voltage V_{WWLn} from −1 V to 5 V can be applied from a corresponding n^{st} write word line WWL, and the outer channel of the write transistor is turned on. A voltage V_{WBL} applied from the write bit line WBL can be −2 V to 0 V, and thus the storage node SN is discharged to −2 V to 0 V. The read bit line RBL and the read word line RWL can read a read current I_{read} smaller than 10⁻¹¹ A (1 E-11 A). The read current I_{read} can enter the DRAM cell from the read bit line RBL, while the read word line RWL can be grounded. For holding the logic state “1”, the voltage V_{WWLn} is kept at −5 V to −1 V, and the write transistor is turned off. The storage node SN is still kept at −2 V to 0 V. The read bit line RBL and the read word line RWL still read a read current I_{read} smaller than 10⁻¹¹ A (1 E-11 A). For programming a logic state “0”, a voltage V_{WWLn} from −1 V to 5 V can be applied to turn on the write transistor. Then, the voltage V_{WBL} can be set at 1 V to 3 V to charge the storage node SN to 1 V to 3 V. In such a condition, the read bit line RBL and the read word line RWL can read a read current I_{read} larger than 10⁻⁹ A (1 E-9 A). For holding the logic state “0”, the voltage V_{WWLn} is kept at −5 V to −1 V, and the write transistor is turned off. The storage node SN is still kept at 1 V to 3 V. The read bit line RBL and the read word line RWL still read a read current I_{read} larger than 10⁻⁹ A (1 E-9 A).

TABLE 1

| Logic | Opera- | | | | |
|---|---|---|---|---|---|
| State | tion | V_{SN} | V_{WWLn} | V_{WBL} | I_{read} |
| “1” | program | −2 V to 0 V | −1 V to 5 V | −2 V to 0 V | <10⁻¹¹ A |
| | read | | −5 V to −1 V | 0 V | |
| “0” | program | 1 V to 3 V | −1 V to 5 V | 1 V to 3 V | >10⁻⁹ A |
| | read | | −5 V to −1 V | 0 V | |

The first transistor T1 and the second transistor T2 can be IGZO transistors. The IGZO transistors have low cut-off currents, and thus are beneficial for enhancing the data retention ability of memory cells. In addition, compared to other types of transistors, the corresponding BEOL electronic components for IGZO transistors need smaller space. With the stacked DRAM structure of the disclosure, a high density 3D DRAM device can be provided.

According to some embodiments, the corresponding first conductive layer 106 can be further serve as a write word line WWL. According to some embodiments, the first conductive pillar 114 can be further serve as a write bit line WBL. According to some embodiments, the second conductive pillar 120 can be further serve as a read word line RWL. According to some embodiments, the third conductive pillar 122 can be further serve as a read bit line RBL.

As described above, the first conductive layers 106, the second conductive layer 112, the first conductive pillar 114, the third conductive layer 118, the second conductive pillar 120, and the third conductive pillar 122 form the first transistors T1 and second transistors T2 of the DRAM structure 100. As such, the device defining region D can be defined to encompass at least the areas of portions of the first conductive layers 106 close to the second conductive layer 112, the second conductive layer 112, the first conductive pillar 114, the third conductive layer 118, the second conductive pillar 120, and the third conductive pillar 122. It should be understood that, in addition to the elements described above, the DRAM cell can be realized to comprise other elements, such as the second dielectric layer 110, the third dielectric layer 116, the first dielectric material 124, the second dielectric material 126, the place holder 128, and/or any other suitable element. For example, the second dielectric layer 110 and the third dielectric layer 116 can serve as gate dielectric layers of the first transistor T1 and the second transistor T2, respectively.

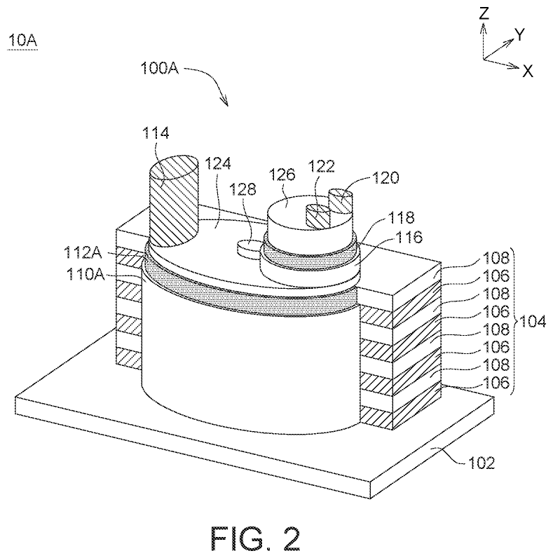

FIG. 2 shows another exemplary semiconductor structure 10A and a DRAM structure 100A thereof. FIG. 2 is a perspective view of the semiconductor structure 10A, in which some portion of some elements are enlarged, and some portion of some other elements are omitted for clarity. The DRAM structure 100A is different from the DRAM structure 100 in that the second dielectric layer 110A and the second conductive layer 112A continuously extends in a stacking direction of the stack 104. They can further across all of the first dielectric layers 108. Other details of the semiconductor structure 10A are similar to those of the semiconductor structure 10, and will not be repeated herein.

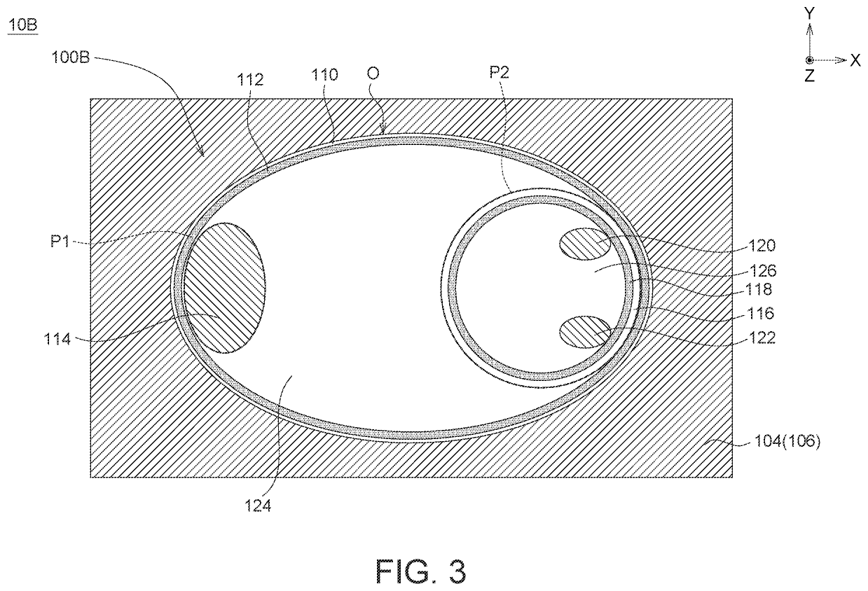

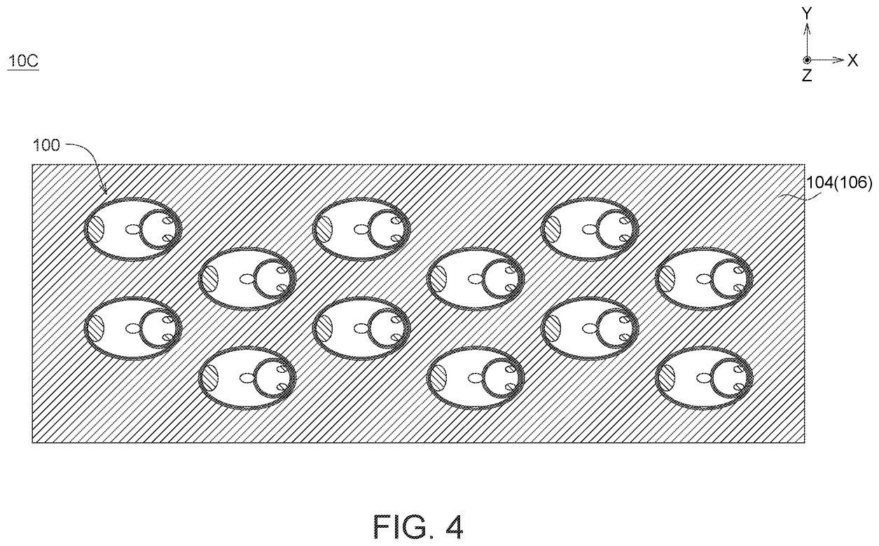

FIG. 3 shows still another exemplary semiconductor structure 10B and a DRAM structure 100B thereof. FIG. 3 is a top view of the semiconductor structure 10B, in which the topmost first dielectric layer 108 is removed for clarity. The DRAM structure 100B is different from the DRAM structure 100 in that the DRAM structure 100B does not comprise the place holder 128. Other details of the semiconductor structure 10B are similar to those of the semiconductor structure 10, and will not be repeated herein.

FIG. 4 shows a further exemplary semiconductor structure 10C and DRAM structures 100 thereof. FIG. 4 is a top view of the semiconductor structure 10B, in which the topmost first dielectric layer 108 is removed for clarity. The semiconductor structure 10C is different from the semiconductor structure 10 in that the semiconductor structure 10C comprises a plurality of DRAM structures 100 disposed on the substrate 102. The DRAM structures 100 share a common stack 104. The DRAM structures 100 can be disposed in a staggered manner, but the disclosure is not limited thereto. Other details of the semiconductor structure 10C are similar to those of the semiconductor structure 10, and will not be repeated herein.

Another aspect of the disclosure is directed to a method for manufacturing a semiconductor structure. The semiconductor structure has a device defining region. The device defining region including a first portion and a second portion separated from each other. The method comprises following steps. First, a stack is formed, the stack comprises a plurality of first conductive layers and a plurality of first dielectric layers disposed alternately, and the stack has an opening through the stack in the device defining region. Then, a second conductive layer is formed along a sidewall of the opening. A first conductive pillar is formed in the opening in the first portion of the device defining region. A third conductive layer is formed in the opening along an edge of the second portion of the device defining region. A second conductive pillar and a third conductive pillar are formed in the second portion, and the second conductive pillar and the third conductive pillar are separated from each other.

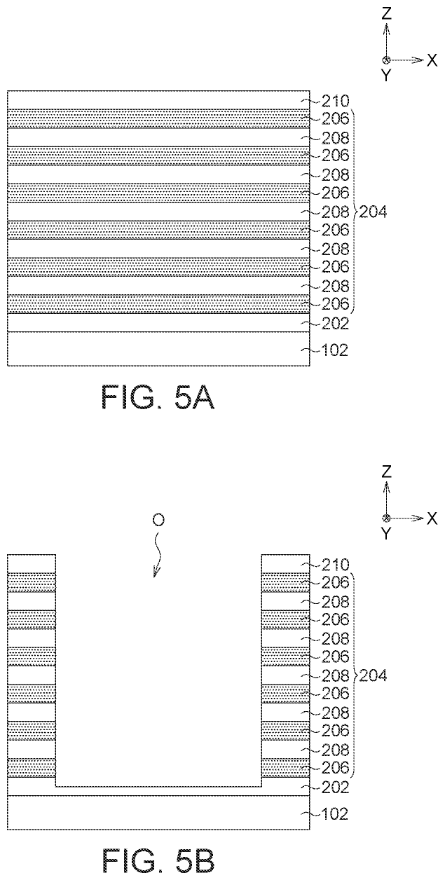

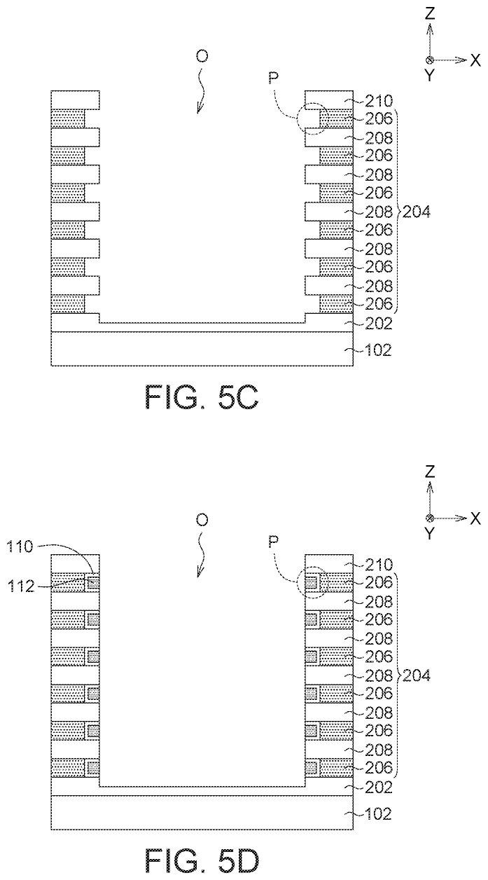

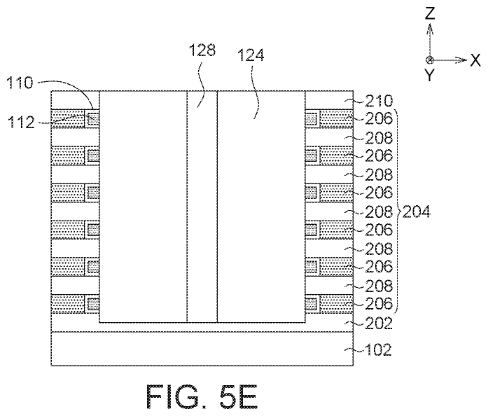

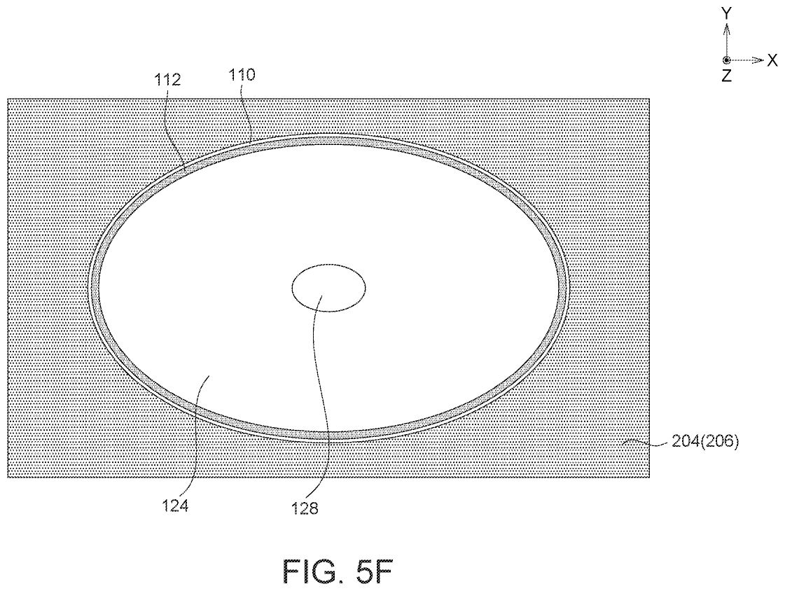

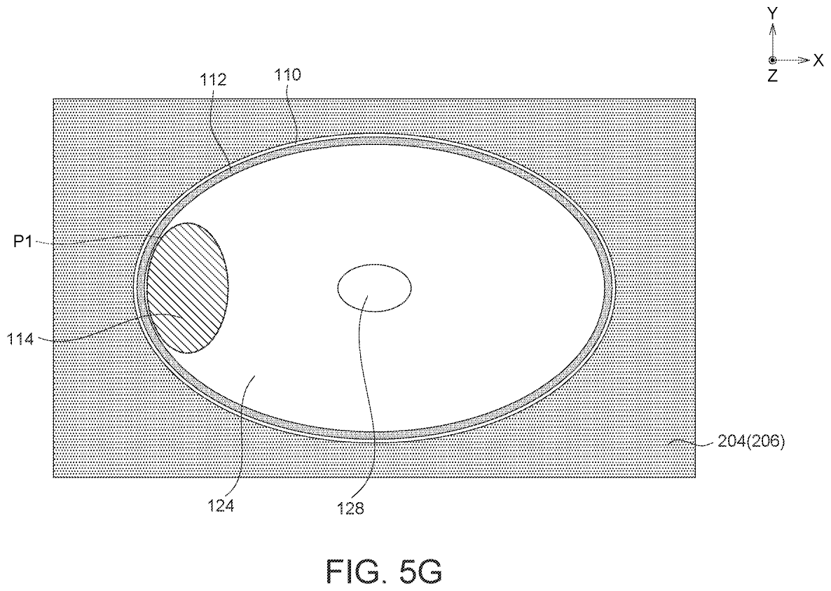

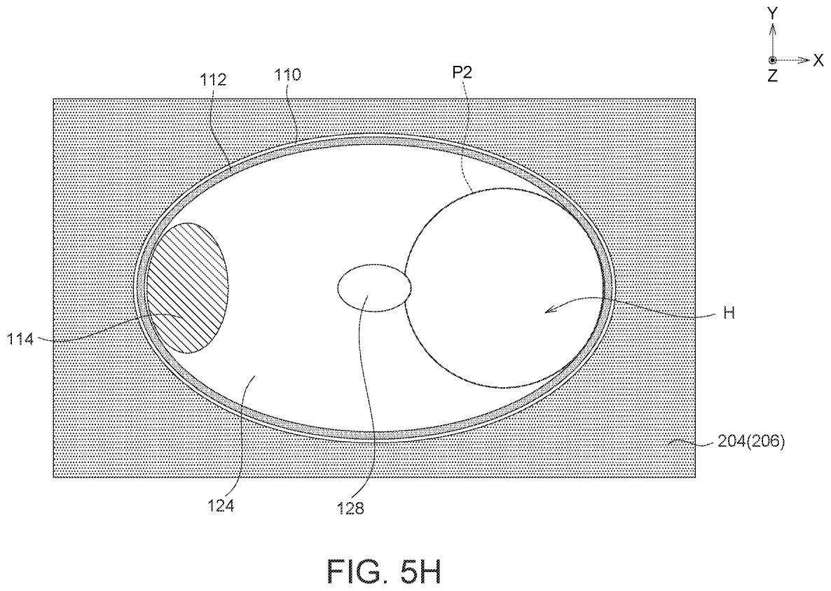

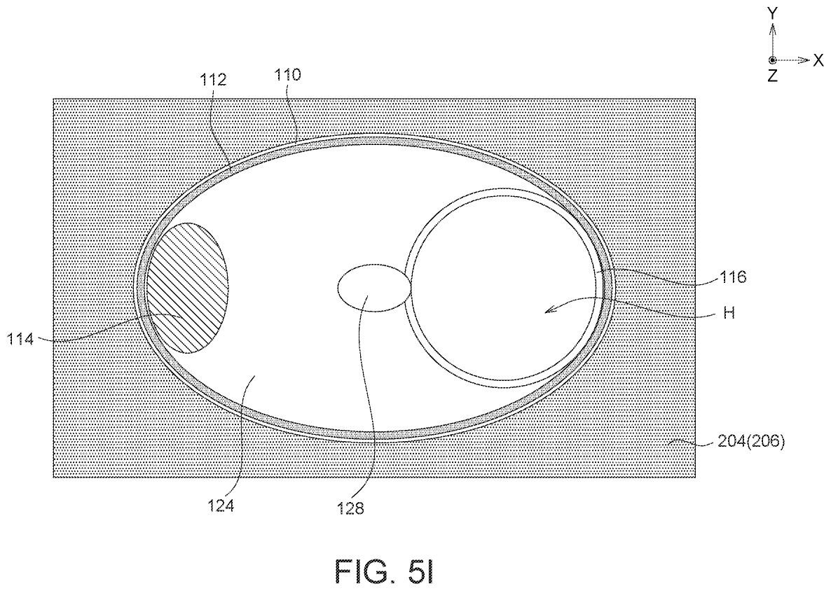

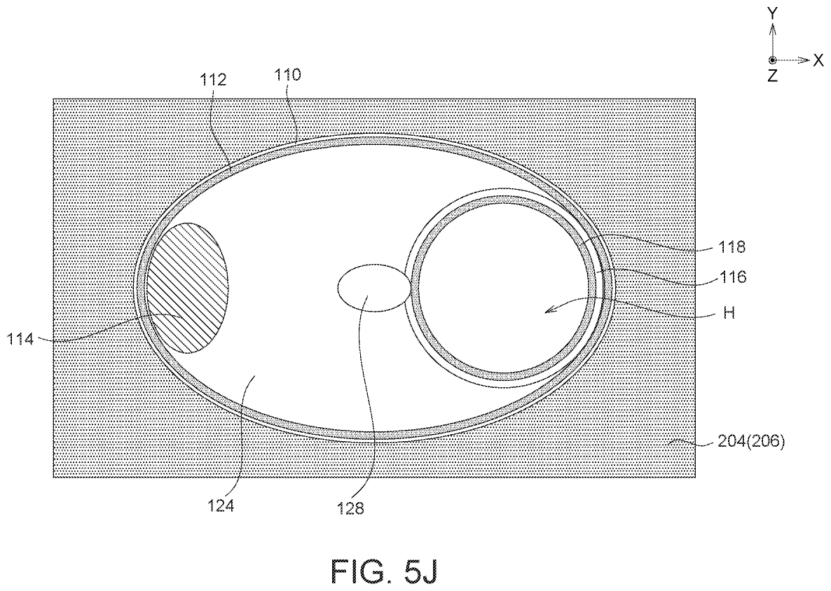

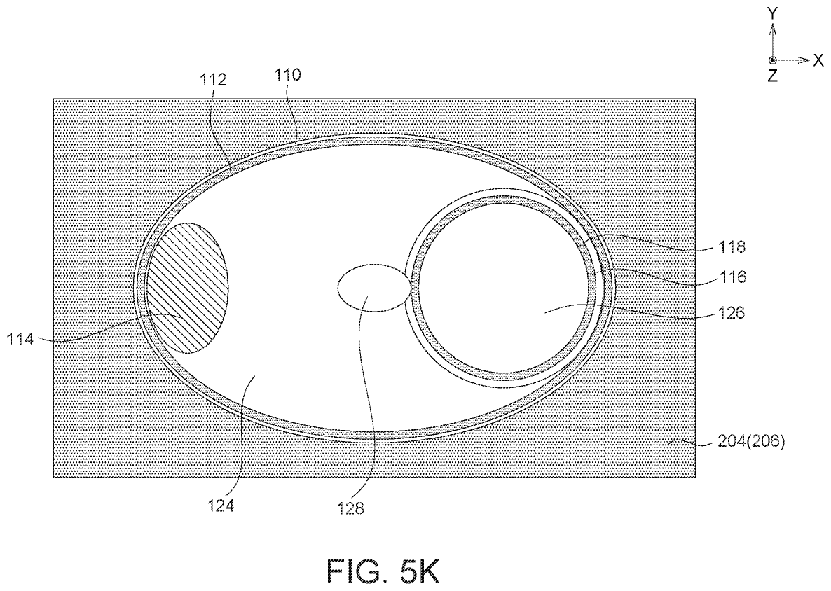

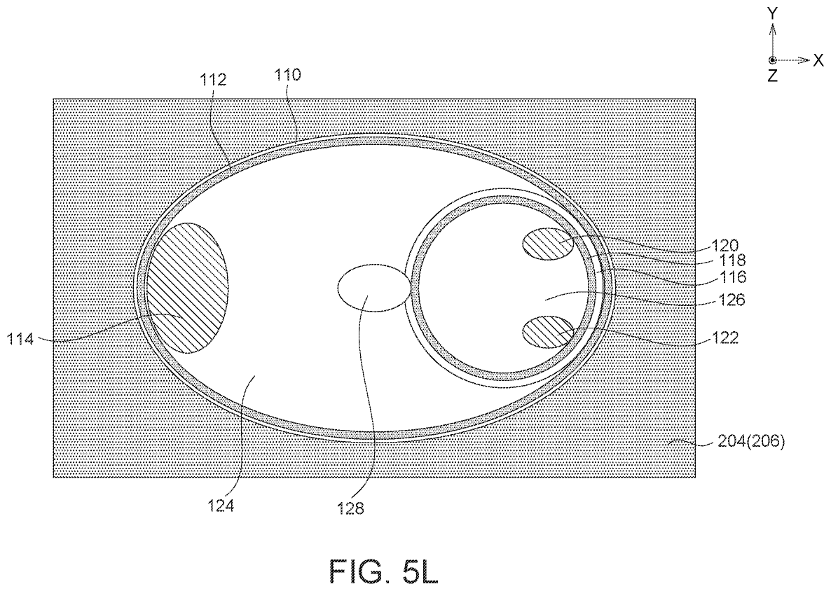

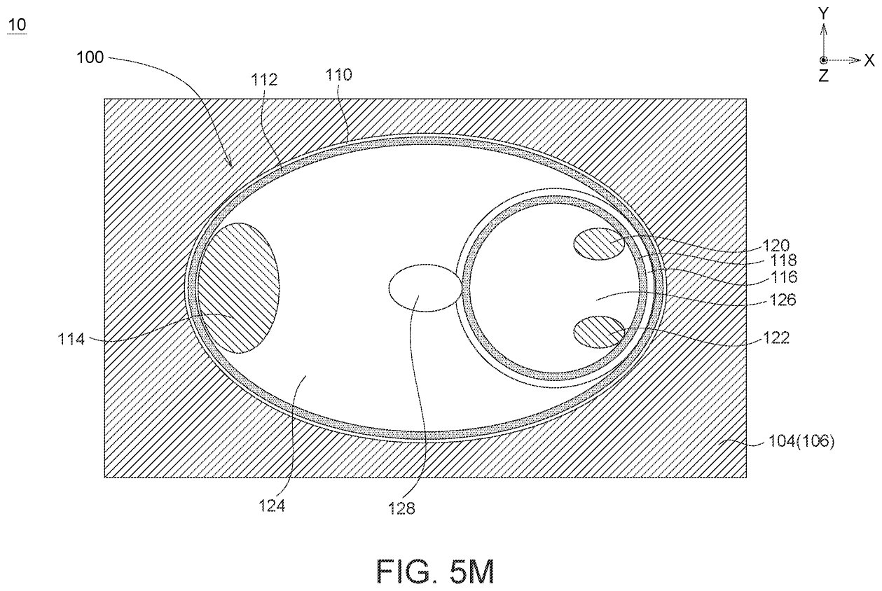

Referring to FIGS. 5A-5M, an exemplary method of the disclosure is shown, which is used for manufacturing the semiconductor structure 10. For clarity, FIGS. 5A-5E illustrate the structure with cross-sectional views, and FIGS. 5F-5M illustrate the structure with top views, in which the hard mask layer 210 is removed, wherein FIG. 5F and FIG. 5E illustrate a same stage of the method. In this exemplary method, a sacrificial material replacing process is used to form the stack 104 of the first conductive layers 106 and the first dielectric layers 108, but it should be understood that the disclosure is not limited thereto.

First, as shown in FIG. 5A, a substrate 102 is provided. Any suitable substrate can be used, without particular limit. Optionally, an interlayer dielectric layer 202 or any other suitable layer can be formed on the substrate 102. The interlayer dielectric layer 202 can be formed of oxide. An initial stack 204 is formed on the substrate 102 and the interlayer dielectric layer 202, if present. The initial stack 204 comprises a plurality of layers 206 of a sacrificial material and a plurality of layers 208 of a dielectric material disposed alternately. The sacrificial material can be silicon nitride. The dielectric material can be oxide. According to some embodiments, a hard mask layer 210 can be formed on the initial stack 204. The hard mask layer 210 can be formed of oxide.

As shown in FIG. 5B, an opening O is formed through the initial stack 204. Optionally, before forming the second dielectric layer 110, the layers 206 of the sacrificial material can be pulled back from the opening O, as shown in FIG. 5C. As such, a plurality of pull-backed portions P of the layers 206 of the sacrificial material are formed. The pull back process can be conducted by wet etching using H₃PO₄ as an etchant or by reactive ion etching.

As shown in FIG. 5D, a second dielectric layer 110 can be formed on a sidewall of the opening O, and particularly can be formed in the pull-backed portions P. The second dielectric layer 110 can be formed of oxide. A second conductive layer 112 can be formed on the second dielectric layer 110. As such, the second conductive layer 112 can be formed along the sidewall of the opening O. The second conductive layer 112 can be formed of a conductive material. It can be understood that, in some other embodiments for the manufacture of the semiconductor structure 10A, the pull-backed portions P are not formed, and the second dielectric layer 110A and the second conductive layer 112A can be formed continuously across the whole initial stack 204 in the stacking direction.

As shown in FIG. 5E and FIG. 5F, a first dielectric material 124 is filled into the opening O. The first dielectric material 124 can be oxide. Optionally, before filling the first dielectric material 124 into the opening O, a place holder 128 can be formed in a central portion of the device defining region D (shown in FIG. 1A). In some embodiments, the formation of the place holder 128 is beneficial for positioning of the components formed in the following processes, particular those will be formed in the first portion P1 and the second portion P2 of the device defining region D. The place holder 128 can be formed of silicon nitride.

As shown in FIG. 5G, a first conductive pillar 114 is formed in the opening O in the first portion P1 of the device defining region D. More specifically, the first conductive pillar 114 is formed through the first dielectric material 124 in the first portion P1. In some embodiments, the scope of the first portion P1 is decided substantially according to the first conductive pillar 114, and the first conductive pillar 114 forms an edge of the first portion P1. The first conductive pillar 114 can continuously extend across the whole initial stack 204 in the stacking direction. The first conductive pillar 114 can be formed of N+ polysilicon.

As shown in FIG. 5H, a hole H is formed through the first dielectric material 124 in the second portion P2 of the device defining region D. In some embodiments, the scope of the second portion P2 is decided substantially according to the third dielectric layer 116 that will be formed in the following process, and the hole H is formed to remove all of the first dielectric material 124 in the second portion P2. The hole H can be formed by reactive ion etching which is highly selective to the conductive material of the second conductive layer 112.

As shown in FIG. 5I, a third dielectric layer 116 can be formed on a sidewall of the hole H. The third dielectric layer 116 can form an edge of the second portion P2 of the device defining region D. The third dielectric layer 116 can be formed of oxide. As shown in FIG. 5J, a third conductive layer 118 can be formed on the third dielectric layer 116. As such, the third conductive layer 118 can be formed in the opening O along the edge of the second portion P2 of the device defining region D. The third conductive layer 118 can be formed of a conductive material.

Then, as shown in FIG. 5K, a second dielectric material 126 is filled into the hole H. The second dielectric material 126 can be oxide. The second dielectric material 126 and the first dielectric material 124 can be the same.

As shown in FIG. 5L, a second conductive pillar 120 and a third conductive pillar 122 are formed in the second portion P2. The second conductive pillar 120 and the third conductive pillar 122 are separated from each other. The second conductive pillar 120 and the third conductive pillar 122 can be formed through the second dielectric material 126. More specifically, the second conductive pillar 120 and the third conductive pillar 122 can continuously extend across the whole initial stack 204 in the stacking direction. The second conductive pillar 120 and the third conductive pillar 122 can be formed of N+ polysilicon.

As shown in FIG. 5M, the sacrificial material of the initial stack 204 can be replaced with a conductive material to form the stack 104. Said stack 104 comprising a plurality of first conductive layers 106 and a plurality of first dielectric layers 108 disposed alternately is thus formed.

As such, the semiconductor structure 10 is thus be formed. According to some embodiments, the first conductive layers 106, the second conductive layer 112, and the first conductive pillar 114 form first transistors T1 of a DRAM structure 100, and the second conductive layer 112, the third conductive layer 118, the second conductive pillar 120, and the third conductive pillar 122 form second transistors of the DRAM structure 100. More specifically, the DRAM structure 100 can comprise a plurality of DRAM cells, each DRAM cell is composed of a first transistor T1 and a second transistor T2. A corresponding first conductive layer 106, a portion of the second conductive layer 112 corresponding to the corresponding first conductive layer 106, and the first conductive pillar 114 form the first transistor T1. The portion of the second conductive layer 112 corresponding to the corresponding first conductive layer 106, the third conductive layer 118, the second conductive pillar 120, and the third conductive pillar 122 form the second transistor T2. In some embodiments, the corresponding first conductive layer 106 forms a first terminal t11 of the first transistor T1, the first conductive pillar 114 forms a second terminal t12 of the first transistor T1, and the portion of the second conductive layer 112 corresponding to the corresponding first conductive layer 106 forms a channel and a third terminal t13 of the first transistor T1. Also, The portion of the second conductive layer 112 corresponding to the corresponding first conductive layer 106 forms a first terminal t21 of the second transistor T2, the second conductive pillar 120 forms a second terminal t22 of the second transistor T2, the third conductive pillar 122 forms a third terminal t23 of the second transistor T2, and the third conductive layer 118 forms a channel of the second transistor T2. In some embodiments, the corresponding first conductive layer 106 further serves as a write word line WWL, the first conductive pillar 114 further serves as a write bit line WBL, the second conductive pillar 120 further serves as a read word line RWL, and the third conductive pillar 122 further serves as a read bit line RBL. Other details of the semiconductor structure 10 have been described above, and will not be repeated herein.

As illustrated above, the semiconductor structure according to the disclosure can be formed by a manufacturing process in which all of the DRAM cells in a 3D DRAM structure are formed by same processes rather than manufactured layer by layer. Such a manufacturing process is also known as a bit cost scalable process, and the cost thereof is reduced compared to a conventional 3D semiconductor process.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, having a device defining region, the device defining region including a first portion and a second portion separated from each other, the semiconductor structure comprising:
a stack comprising a plurality of first conductive layers and a plurality of first dielectric layers disposed alternately, the stack having an opening through the stack in the device defining region;
a second conductive layer disposed along a sidewall of the opening;
a first conductive pillar disposed in the opening in the first portion of the device defining region;
a third conductive layer disposed in the opening along an edge of the second portion of the device defining region; and
a second conductive pillar and a third conductive pillar disposed in the second portion and separated from each other.

2. The semiconductor structure according to claim 1, further comprising:
a second dielectric layer disposed on the sidewall of the opening, wherein the second conductive layer is disposed on the second dielectric layer; and
a third dielectric layer disposed as an outermost layer of the second portion, wherein the third conductive layer is disposed on the third dielectric layer.

3. The semiconductor structure according to claim 1, further comprising:
a first dielectric material filling a remaining space of the opening except for the first portion and the second portion; and
a second dielectric material filling a remaining space of the second portion.

4. The semiconductor structure according to claim 1, further comprising:
a place holder disposed in a central portion of the device defining region, wherein the first portion and the second portion are positioned at two opposite sides of the place holder.

5. The semiconductor structure according to claim 1, wherein the second conductive layer discontinuously extends in a stacking direction of the stack.

6. The semiconductor structure according to claim 1, wherein the second conductive layer continuously extends in a stacking direction of the stack.

7. The semiconductor structure according to claim 1, comprising:
a substrate; and
a DRAM structure disposed on the substrate, wherein the first conductive layers, the second conductive layer, and the first conductive pillar form first transistors of the DRAM structure, and the second conductive layer, the third conductive layer, the second conductive pillar, and the third conductive pillar form second transistors of the DRAM structure.

8. The semiconductor structure according to claim 7, wherein the DRAM structure comprising a plurality of DRAM cells, each DRAM cell is composed of a first transistor and a second transistor, a corresponding first conductive layer, a portion of the second conductive layer corresponding to the corresponding first conductive layer, and the first conductive pillar form the first transistor, and the portion of the second conductive layer corresponding to the corresponding first conductive layer, the third conductive layer, the second conductive pillar, and the third conductive pillar form the second transistor.

9. The semiconductor structure according to claim 8, wherein the corresponding first conductive layer forms a first terminal of the first transistor, the first conductive pillar forms a second terminal of the first transistor, and the portion of the second conductive layer corresponding to the corresponding first conductive layer forms a channel and a third terminal of the first transistor, and wherein the portion of the second conductive layer corresponding to the corresponding first conductive layer forms a first terminal of the second transistor, the second conductive pillar forms a second terminal of the second transistor, the third conductive pillar forms a third terminal of the second transistor, and the third conductive layer forms a channel of the second transistor.

10. The semiconductor structure according to claim 9, wherein the first terminal of the first transistor is a gate terminal of the first transistor, the second terminal of the first transistor is a drain terminal of the first transistor, and the third terminal of the first transistor is a source terminal of the first transistor, and wherein the first terminal of the second transistor is a gate terminal of the second transistor, the second terminal of the second transistor is a drain terminal of the second transistor, and the third terminal of the second transistor is a source terminal of the second transistor.

11. The semiconductor structure according to claim 9, wherein the corresponding first conductive layer further serves as a write word line, the first conductive pillar further serves as a write bit line, the second conductive pillar further serves as a read word line, and the third conductive pillar further serves as a read bit line.

12. The semiconductor structure according to claim 8, wherein the first transistor is a write transistor, and the second transistor is a read transistor.

13. The semiconductor structure according to claim 8, comprising:
a plurality of the DRAM structure disposed on the substrate, wherein the DRAM structures share a common stack.

14. A method for manufacturing a semiconductor structure, the semiconductor structure having a device defining region, the device defining region including a first portion and a second portion separated from each other, the method comprising:
forming a stack comprising a plurality of first conductive layers and a plurality of first dielectric layers disposed alternately, the stack having an opening through the stack in the device defining region;
forming a second conductive layer along a sidewall of the opening;
forming a first conductive pillar in the opening in the first portion of the device defining region;
forming a third conductive layer in the opening along an edge of the second portion of the device defining region; and
forming a second conductive pillar and a third conductive pillar in the second portion, wherein the second conductive pillar and the third conductive pillar are separated from each other.

15. The method according to claim 14, comprising:
forming an initial stack on a substrate, the initial stack comprising a plurality of layers of a sacrificial material and a plurality of layers of a dielectric material disposed alternately;
forming the opening through the initial stack;
forming a second dielectric layer on the sidewall of the opening;
forming the second conductive layer on the second dielectric layer;
filling a first dielectric material into the opening;
forming a hole through the first dielectric material in the second portion of the device defining region;
forming a third dielectric layer on a sidewall of the hole;
forming the third conductive layer on the third dielectric layer;
filling a second dielectric material into the hole;
forming the second conductive pillar and the third conductive pillar through the second dielectric material; and
replacing the sacrificial material of the initial stack with a conductive material to form the stack.

16. The method according to claim 15, further comprising:
before forming the second dielectric layer, pulling back the layers of the sacrificial material from the opening.

17. The method according to claim 15, further comprising:
before filling the first dielectric material into the opening, forming a place holder in a central portion of the device defining region.

18. The method according to claim 14, wherein the first conductive layers, the second conductive layer, and the first conductive pillar form first transistors of a DRAM structure, and the second conductive layer, the third conductive layer, the second conductive pillar, and the third conductive pillar form second transistors of the DRAM structure.

19. The method according to claim 18, wherein the DRAM structure comprising a plurality of DRAM cells, each DRAM cell is composed of a first transistor and a second transistor, a corresponding first conductive layer, a portion of the second conductive layer corresponding to the corresponding first conductive layer, and the first conductive pillar form the first transistor, and the portion of the second conductive layer corresponding to the corresponding first conductive layer, the third conductive layer, the second conductive pillar, and the third conductive pillar form the second transistor.

20. The method according to claim 19,
wherein the corresponding first conductive layer forms a first terminal of the first transistor, the first conductive pillar forms a second terminal of the first transistor, and the portion of the second conductive layer corresponding to the corresponding first conductive layer forms a channel and a third terminal of the first transistor, and wherein the portion of the second conductive layer corresponding to the corresponding first conductive layer forms a first terminal of the second transistor, the second conductive pillar forms a second terminal of the second transistor, the third conductive pillar forms a third terminal of the second transistor, and the third conductive layer forms a channel of the second transistor; and
wherein the corresponding first conductive layer further serves as a write word line, the first conductive pillar further serves as a write bit line, the second conductive pillar further serves as a read word line, and the third conductive pillar further serves as a read bit line.
